(19) United States
(12) Patent Application Publication
(10) Pub. No.: US 2007/0279829 A1
(43) Pub. Date: Dec. 6, 2007

(54) CONTROL SYSTEM FOR STATIC NEUTRALIZER

(75) Inventors: Peter Gefter, South San Francisco, CA (US); Edward Oldynski, Martinez, CA (US); Brian Warren, Reno, NV (US)

Correspondence Address: URIARTE LAW, 257 RODONOVAN DRIVE, SANTA CLARA, CA, 95051, US

(73) Assignee: MKS Instruments, Inc., Wilmington, MA (US)

(21) Appl. No.: 11/697,209

(22) Filed: Apr. 5, 2007

Related U.S. Application Data
(60) Provisional application No. 60/790,424, filed on Apr. 6, 2006.

(51) Int. Cl. H01T 23/00; G11C 17/00; H05F 3/06

(52) U.S. Cl. 361/213; 361/235; 365/94

(57) ABSTRACT

The present invention pertains to various embodiments for managing ion current balance by independently controlling positive ion current and negative ion current generated during static neutralization. In another embodiment, E-Field compensation may be provided. These embodiments disclose both method and apparatus implementations.

### CROSS REFERENCE TO RELATED APPLICATIONS

This non-provisional application claims, pursuant to 35 U.S.C. 119(e), the benefit of provisional application 60/790, 424, filed 6 Apr. 2006 and entitled “Control System for Static Neutralizer”.

### BACKGROUND

(1) Technical Field

The present invention relates to static neutralizers, which are designed to eliminate or minimize static charge accumulation of an object. These static neutralizers compensate the static charge by generating bipolar air, or in some instances gas, ions and delivering these air or gas ions to a charged object.

(2) Background Art

A static neutralizer is commonly used to remove unwanted or destructive electro-static potential from a charged object, named “target”. Generally, a static neutralizer employs a set of electrodes, sometimes referred to as emitters, ionizing electrodes or corona electrodes, that each have a shape suitable for generating ions by corona discharge when a voltage, named “ionizing voltage”, of sufficient magnitude exceeds a corona on-set threshold voltage, named “corona threshold”. A common ionizing electrode shape includes a long thin cylindrical shape, such as a wire, or an end portion having a small tip radius or a sharp point.

These emitters are positioned generally near the target so that most of the ions created during corona discharge neutralize the charge held by the target rather than be lost to recombination or grounding. One common approach for generating ions includes oscillating or pulsing the ionizing voltage so that it equals or exceeds the corona threshold in both positive and negative polarities, creating a set of ions that includes positive ions and negative ions. A mix of ions that includes ions of opposite polarity is sometimes referred to as a bipolar ion cloud or bipolar ions. These ions may be formed from molecules provided by a gas or a mix of gases, such as air. If these ions are created in an environment filled with air, these ions are sometimes referred to as air ions.

To efficiently and effectively neutralize a target, much effort is made to generate an optimal balance of positive and negative ions. The difference between the number of positive ions and negative ions reaching the target is commonly referred to as ion balance, and this ion balance is typically set prior to first use of the static neutralizer by the end user. However, the ion balance of a static neutralizer is affected by many factors and may change overtime. For example, the emitters may accumulate debris due to air or gas borne contaminants, or the emitters may degrade or erode. Either or both of these conditions may cause the positive ion balance, the negative ion balance or both to change from their original settings. This change in ion balance, named ion balance drift, if left uncorrected, may drift out of a specified voltage range, disrupting the optimal ion balance and decreasing the efficiency of the static neutralizer.

Ion balance can usually be restored by removing or cleaning debris from the contaminated ionizing electrode. However, this approach is less than optimal since it requires the static neutralizer to be placed out of operation during cleaning, which may interrupt production and cause added expense and delay.

Another solution includes using two power supplies to respectively generate positive and negative ions, measuring the currents between each power supply and earth ground, respectively, and using these measured currents to determine the positive and negative ion output of the static neutralizer. When air ions are produced and transported to a target or to the reference electrode, the power supply that provided the corona voltage loses that same quantity of charge, resulting in a current of the same polarity flowing from ground to the ground rail of the power supply power bus if it is a positive current, or from the ground rail of the power supply power bus to ground if it is a negative current.

Measuring the currents between ground and the positive power supply and between ground and the negative power supply was a successful prior art approach, providing that there were separate positive and negative emitters. For simplicity, these currents may be hereinafter referred to as return currents, whether positive or negative.

The positive return current and the negative return current were respectively used to correlate with the positive and negative ion output provided by the static neutralizer, while differences between the positive and negative return currents measured were used to correlate with ion balance. This ion balance was then used to adjust or control ion balance.

But using return currents to determine and control ion balance results in ion current and ion measuring problems if both power supplies energize the same set of emitters through one high voltage bus. As a result, present solutions separately connect the positive power supply to a first set of emitters, named “positive emitters”, and the negative power supply to a second set of emitters, named “negative emitters”, so that the positive emitters do not receive a corona voltage from the negative power supply and the negative emitters do not receive a corona voltage from the positive power supply during operation. Using separate sets of positive and negative emitters, however, leads to another set of problems, such as increasing static neutralizer production complexity, and therefore, cost.

In addition, determining the positive air ion output and the negative air ion output separately requires two current measuring circuits, with one current measuring circuit for each polarity of ion output created. The first current measuring circuit measures the return current between the positive power supply and ground, while the second current measuring circuit measures the return current between the negative power supply and ground.

FIG. 1 depicts a known static neutralizer 10 that uses two current measuring circuits 12 and 14. Static neutralizer 10 is of the DC pulsed variety, such as the those taught in U.S. Pat. No. 5,930,105, entitled “Method and Apparatus for Air Ionization” and in U.S. Pat. No. 6,130,815, entitled “Apparatus and Method for Monitoring of Air Ionization”, collectively referred herein as the Patents. When operated during a first time period, a positive high voltage power supply 16 provides a positive voltage 18 on an emitter array 20 through a summing block 22, creating positive air ions 24 when positive voltage 18 reaches a corona threshold supported by static neutralizer 10. Positive high voltage power supply 16 also produces a power supply current 29 in the summing block 22, which flows through negative power supply 30, negative current measuring circuit 14, ground 26 and current measuring circuit 12. As positive air ions 24 are generated, electrons flow from emitter array 20 toward ground 26 and a positive current 28 results. Positive current 28 then flows from ground 26 through current measuring circuit 12. The magnitude of the positive current 28 is proportional to the ion current production rate of positive air ions 24 plus power supply current 29.

During a second time period, a negative high voltage power supply 30 provides a negative voltage 32 on emitter array 20 through summing block 22, creating negative air ions 34. Negative high voltage power supply 30 also produces a power supply current 31 that flows from negative high voltage power supply 30, current measuring circuit 14, ground, current measuring circuit 12 and positive high voltage power supply 16. In addition, as negative air ions 34 are generated, electrons flow outward, toward target 36, from emitter array 20, and a negative current 38 results. Negative current 38 flows to ground 26 through current measuring circuit 14. The magnitude of negative current 38 is proportional to the ion current production rate of negative air ions 34 plus power supply current 31.

Positive air ions 24 and negative air ions 34 are mixed and directed, such as by using a directed flow of gas or air, to target 36. Ion balance at target 36 is achieved when the arrival rates of positive air ions 24 and negative air ions 34 are equal. The circuit solution in FIG. 1 suffers from a problem of much greater power supply currents 29 and 31 that mask or swamp the return currents representing positive air ions 24 and negative air ions 34, making it and nearly impossible to measure these return currents with any degree of certainty

Another problem with the solution discussed above includes measurement error and measurement stability. Measuring positive and negative return currents, calculating their differences, and then using the differences to determine ion balance in a static neutralizer is not optimal because these return currents are relatively large when compared to their differences. Since ion balance may be defined to include the difference between a positive return current and a negative current, the return current numbers should be relatively large compared to their difference. The difference between the average positive return current and the average negative return may be nearly zero, but deviations around the average ion balance may be large. Thus, prior solutions that use this approach suffer from balance errors that are determined by the magnitude of the two large numbers rather than the magnitude of the ion balance itself.

A further problem concerns non-representative waveform sampling. In brief, transition currents are averaged into the middle period current. A current waveform (ground to power supply) has a rise period, a low slope middle period, and a fall period. Ignoring the current during the rise and fall periods would be beneficial. A superior measure of air ion production and air ion balance is achieved with only the middle period current.

Another problem involves interaction between the ionizer's feedback adjustment and balance within a target zone. One purpose of feedback technology is to maintain a balance of positive and negative air ions in the target zone. However, some prior art feedback systems operate by changing their respective emitter voltage to adjust ion balance. When emitter voltage is changed, the mobility of air ions is changed because the electric field is different. This causes an ion balance shift at the target.

Consider the case where contamination builds up on a negative emitter. Negative air ion production would decrease. At the ionizer, this would be quantified by a decrease in the negative return current. In response, prior solutions include increasing the corona voltage applied to the negative emitter until the negative return current is restored to a prior determined value.

Increasing the negative voltage at the negative emitter increases the electrical field strength and size that is created between the emitter and the target. A stronger negative electrical field will increase the velocity of negative ions affected by the electrical filed, causing the negative ions to be propelled towards the target at a greater velocity that positive ions. This in turn, will cause ion balance to shift towards a negative bias.

Consequently, there is a need for a control system for static neutralizers that minimizes or avoids some or all of the above described problems.

### SUMMARY

The present invention pertains to various embodiments for managing ion current balance by independently controlling positive ion current and negative ion current generated during static neutralization. In another embodiment, E-Field compensation may be provided. These embodiments disclose both method and apparatus implementations.

### BRIEF DESCRIPTION OF THE DRAWINGS

FIG. 1 is a diagram of a prior art static neutralizer that uses two return current measuring circuits;

FIG. 2 illustrates a control system for maintaining ion current balance by independently controlling the positive ion current and the negative ion current of a static neutralizer in accordance with one embodiment of the present invention.

FIG. 3 is a block diagram of a portion of the embodiment disclosed in FIG. 2 that shows the flow of positive return current while the positive HVPS is powered-on during a first time period;

FIG. 4 is a block diagram of a portion of the embodiment disclosed in FIG. 2 that includes the flow of negative return current when the negative HVPS is powered-on during a second time period;

FIG. 5 illustrates an example feedback voltage waveform that represents a feedback voltage generated by a current measuring circuit, such as the current measurement circuit used by the embodiment disclosed in FIG. 2, during a full emitter cycle;

FIG. 6 illustrates two positive emitter voltages that have equal time voltage waveform areas and which are created through a control system for a static neutralizer in order to compensate the charge plate monitor inaccuracy in accordance with another embodiment of the present invention;

FIG. 7 is a process flow illustrating a method of maintaining ion current balance by independently controlling the positive ion current and the negative ion current of a static neutralizer in accordance with another embodiment of the present invention;

FIG. 8 illustrates a method of performing current correction in a control system that maintains ion current balance for a static neutralizer in accordance with another embodiment of the present invention;

FIG. 9 shows the method illustrated in FIG. 8 modified to include performing E-Filed balance compensation in accordance with a further embodiment of the present invention.

FIG. 10 is a block diagram illustrating a method of adjusting the high voltage power supplies to provide a constant current that may be used with the method in FIG. 6 above in accordance with a further embodiment of the present invention; and

FIG. 11 is a method of performing electrical field compensation that may be used with the method in FIG. 8 above in accordance with yet another embodiment of the present invention.

### DETAILED DESCRIPTION OF THE INVENTION

In the following detailed description, for purposes of explanation, numerous specific details are set forth to provide a thorough understanding of the various embodiments of the present invention. Those of ordinary skill in the art will realize that these various embodiments of the present invention are illustrative only and are not intended to be limiting in any way. Other embodiments of the present invention will readily suggest themselves to such skilled persons having benefit of the disclosure herein.

In addition, for clarity purposes, not all of the routine features of the embodiments described herein are shown or described. It is appreciated that in the development of any such actual implementation, numerous implementation-specific decisions must be made to achieve the developer's specific goals. These specific goals will vary from one implementation to another and from one developer to another. Moreover, it will be appreciated that such a development effort might be complex and time-consuming but would nevertheless be a routine engineering undertaking for those of ordinary skill in the art having the benefit of the herein disclosure.

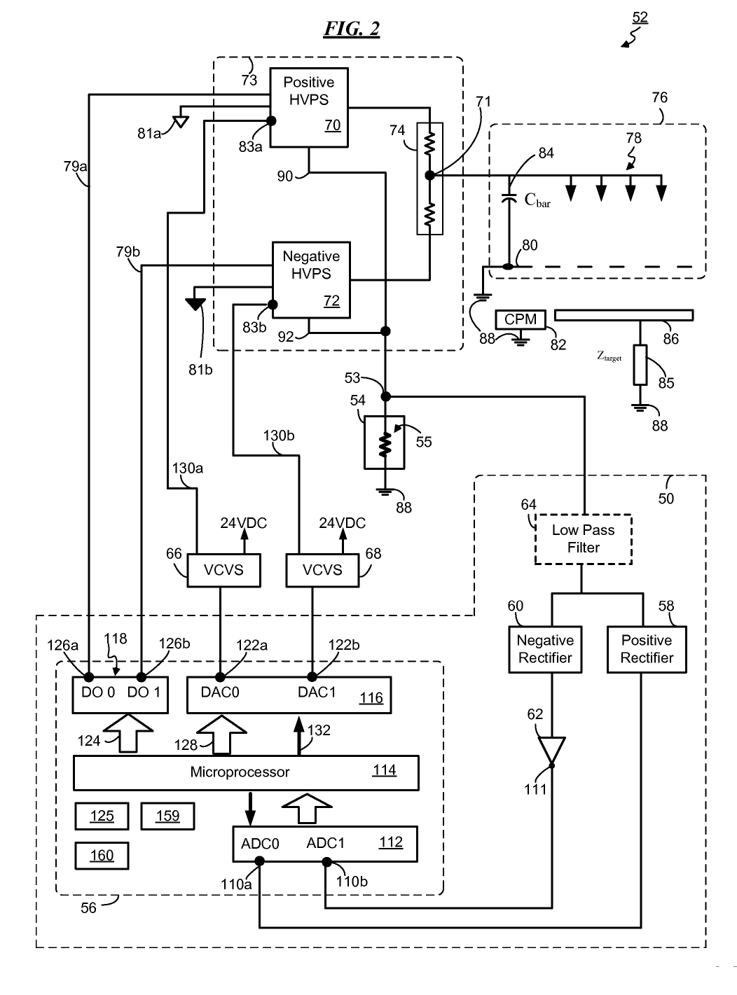

FIG. 2 illustrates a control system 50 for maintaining ion current balance by independently controlling the positive ion current and the negative ion current of a static neutralizer 52 in accordance with one embodiment of the present invention. Control system 50 includes a current measuring circuit 54, microcontroller 56, rectifiers 58 and 60, and an inverter 62, which are disposed in the manner shown. Control system 50 may also optionally include a low pass filter 64, voltage controlled voltage sources 66 and 68 or both. Static neutralizer 52 may include a positive HVPS, sometimes referred to as a positive high voltage power supply, 70; a negative HVPS, sometimes referred to as a negative high voltage power supply, 72; a summing block 74 and an emitter module 76 having an emitter set of at least one emitter, such as emitter array 78.

Positive and negative HVPS 70 and 72 may respectively include control inputs 79a and 79b for receiving control signals, including power-on and power-off signals, from a control system, such as control system 50; control common lines 81a and 81b and voltage output level control inputs 3a and 82b or receiving voltage magnitude control signals through level control input lines 130a and 130b from control system 50. High voltage power supplies that generate high voltages that can be turned-on or off through the power supply control inputs 79a and 79b and that can be adjusted to have a certain voltage magnitude exist and are known, and consequently, are not further disclosed in detail to avoid overcomplicating the herein disclosure.

FIG. 2 also shows a charge plate monitor 80, named “CPM”, that is coupled to a sensor 82 and a target 86 selected for neutralization, which, either collectively or individually, are not a necessary part of control system 50 and static neutralizer 52 but included to facilitate the herein disclosure. A capacitor 84 and impedance 85 are also included to show impedance through which power supply current may be lost.

Current measuring circuit 54 is disposed to measure the current flowing between positive and negative HVPS 70 and 72, emitter(s) 78 and ground 88. Since the current measured represents the flow of current between a HVPS and ground via emitter(s) 78, it is hereinafter referred to as “return current”. As shown in the example disclosed in FIG. 2, current measuring circuit 54 may be implemented in the form of a resistor 55, which is coupled in series between ground 88 and the respective ground rail portions 90 and 92 of the power buses for positive and negative HVPS 70 and 72, respectively.

Emitters 78 may be housed within an emitter module 76 and are each coupled to an output 71 of summing block 74. In alternative embodiment (not shown), emitters 78 may include two sets of emitters with a first set of emitters disposed to receive the output of positive HVPS 70 and a second set of emitters disposed to receive the output of negative HVPS 72. The emitters in the first set may hereinafter be referred to as “positive emitters”, while the emitters in the second set may hereinafter be referred to as “negative emitters”.

At current measuring circuit output 53, resistor 55 provides a voltage having a magnitude and direction that reflects the magnitude and direction of a current flowing through resistor 55. This relationship is commonly known as Ohm's law, which states that voltage is equal to the product of the current flowing through a resistor, such as resistor 55, and the resistance value of the resistor. It is currently contemplated that resistor 55 has a resistance value that reflects a broad range of current values that can flow between the power supplies during operation, such as a resistance value within the approximate range of 1K to 1 MEG ohms. This resistance range is not intended to limit the present invention in anyway but is provided simply to show one type of current measuring circuit that may be used to measure return current, such as positive return current 98 or negative return current 104, discussed below.

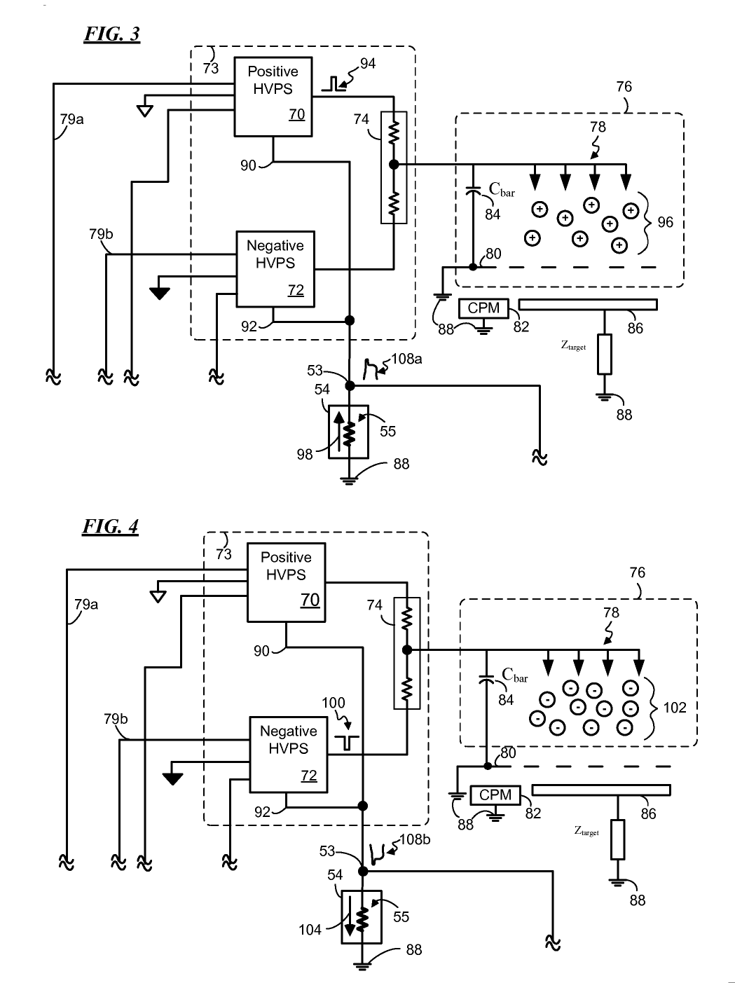

For example and with reference to FIGS. 2 and 3, during a first time period, microcontroller 56 activates DC pulsed bi-polar power supply 73 so that positive HVPS 70 generates a positive voltage pulse 94, which conducts to emitter module 76 through summing block 74. Positive voltage pulse 94 reaches at least one emitter from emitter array 78, and when the amplitude of positive voltage pulse 94 exceeds the corona threshold voltage for emitter module 76, positive air ions 96 are created by corona discharge. In proportion to the amount of positive air ions generated by corona discharge, electrons flow to ground and return to positive high voltage supply 70 through current measuring circuit 54. The flow of electrons from ground to positive HVPS 70 is herein referred to as a positive return current 98.

The term air ions when used in this disclosure is not intended to be limited to ions formed solely from air molecules but may include ions created in an environment comprised of molecules of a single type of gas or a combination of gases that may or may not include a group of gases commonly referred to as air.

In another example and with reference to FIGS. 2 and 4, during a second time period, microcontroller 56 activates DC pulsed bi-polar power supply 73 so that negative HVPS 70 generates a negative voltage pulse 100, which conducts to emitter module 76 through summing block 74. Negative voltage pulse 100 reaches at least one emitter from emitter array 78, and when negative voltage 100 exceeds the corona threshold voltage for emitter module 76, negative air ions 102 are created by corona discharge. In proportion to the amount of negative air ions generated by corona discharge, electrons flow from negative high voltage supply 72 to ground 88 through current measuring circuit 54. The flow of electrons from high voltage power supply 72 is herein referred to as a negative return current 104.

In each of the examples above, current measuring circuit 54 generates a voltage, named feedback voltage, at current measuring circuit output 54. In the current embodiment, this feedback voltage has a magnitude and direction, which may be expressed as voltage polarity, that reflect the magnitude and direction of positive return current 98 or negative return current 104. For example in FIG. 3, current measuring circuit 54 will generate a feedback voltage 108a that has a positive polarity when positive return current 98 flows through current measuring circuit 54 during the first time period, while in FIG. 4 current measuring circuit 54 will generate a feedback voltage 108b that has a negative polarity when negative return current 104 flows through current measuring circuit 54 during the second time period. Feedback voltages 108a and 108b may be calculated using Ohm's law as previously described above.

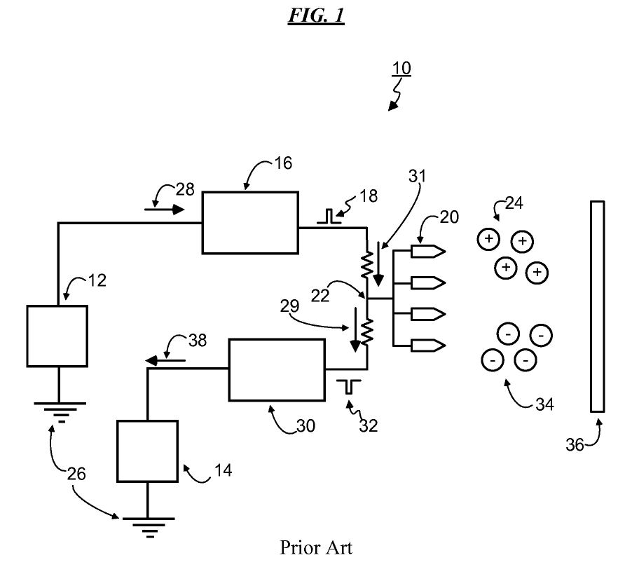

As seen in FIG. 1, feedback voltages 108a and 108b are received by rectifiers 58 and 60. In an alternative embodiment, feedback voltage 108a and 108b may first be filtered through a low pass filter 64 to reduce signal noise. It is currently contemplated that low pass filter 64 attenuates or blocks electrical signal portions of feedback voltage above 200 Hz. The use of low pass filter 64 or the filter threshold of 200 Hz is not intended to limit the various embodiments of the present invention that are disclosed herein.

Rectifier 58 or 60 respectively route feedback voltage 108a or 108b by polarity either to first port 110a or second port 110b. Rectifiers 58 and 60 may be implemented by using precision rectifiers. A precision rectifier generally operates by receiving a signal of either polarity but only permits an output signal to pass through the rectifier of a single polarity. The embodiment shown is not intended to be limited to the use of precision rectifiers, and other types of elements may be used that provide the function of routing the feedback voltage generated by current measuring circuit 54 into first and second ports 110a and 110b according to the polarity of the feedback voltage. For example, in an alternative embodiment, a diode or its equivalent may be used. Diodes and precision rectifiers are known in the art.

Rectifier 58 is disposed to only permit voltage of positive polarity, also referred to as a positive voltage, to reach first port 110a, while rectifier 60 is disposed to only permit a voltage of negative polarity to reach inverter 62. Inverter 62 has an inverter output 111 that generates an output voltage having a magnitude equivalent to the input voltage received but with an opposite polarity. In the embodiment disclosed in FIG. 2 and since inverter 62 is disposed to receive only negative feedback voltages, inverter output 111 will provide an output voltage that is directly proportional to the magnitude of the negative feedback voltage received by inverter 62 but has a positive polarity. The output voltage provided by inverter output 111 is received by port 110b. Rectifier 58 limits first port 110a to receive only a positive voltage that has a magnitude directly proportional to feedback voltage 108a. Rectifier 60 and inverter 62 limit second port 110b to receive only a positive voltage that has a magnitude directly and inversely proportional to the magnitude of feedback voltage 108b.

First and second ADC ports 110a and 110b are provided by an analog-to-digital converter, named ADC, 112, which is part of microcontroller 56. Besides ADC 112, microcontroller 56 may further include a microprocessor 114, a digital to analog converter, named DAC, 116, a digital output 118 and a memory 120. Microcontroller 56 may be implemented using model C8051F043, from Silicon Laboratories, Inc. of Austin, Tex. The use of this particular microcontroller is not intended to limit the present invention in any way. Other types of microcontrollers may be used or the configuration shown in FIG. 1 may be implemented using separately obtained components.

In addition, ADC 112 and DAC 116 are both operated in single-ended mode to obtain the widest resolution possible for their given resolutions. ADC 112 has a digital resolution of 12 bits, which translates to a quantization of 4096 levels when operated in single-ended mode. In an alternative embodiment, if inverter 62 is not used and the output of rectifier 60 is received directly by second port 110b, ADC 112 may be operated in differential mode but will result in half of the available resolution. ADC 112 has an analog resolution range of 0 to 2.40 volts although this resolution range is not intended to be limiting in any way. Any analog resolution range may be used that will accurately measure and capture the full range of feedback voltage that will be received and sampled by microcontroller 56 though ADC 112.

DAC 116 includes DAC output ports 122a and 122b and is capable of converting a digital value, which may be received from microprocessor 114 through a bus 124, into an analog signal. This analog signal may be asserted through at least one DAC 116 output port, such as DAC output port 122a or 122b. The minimum and maximum digital values in which DAC 116 can convert into an analog signal is commonly referred to its digital resolution and in the current embodiment is 12 bits in width, resulting in a digital resolution range of 0 through 4096. In addition, ports 122a and 122b can assert an analog signal within the range of 0 to 2.40 volts, named “analog output signal range,” in a linear proportion to the value of the digital value. Digital to analog controllers are known, and the digital resolution range, analog signal output range and the linearity or non-linearity of the digital to analog conversion taught for the example disclosed herein is not intended to limit the present invention in anyway. Other ranges may be used by those of ordinary skill in the art having the benefit of this disclosure.

In an alternative embodiment (not shown), inverter 62 may be omitted and the output of negative rectifier 60 directly coupled to second port 110b. In this event, one of the 12 bits used by ADC 112 should be used to reflect polarity of the signals received by first and second ports 110a and 110b, reducing the resolution of ADC 112 to half of its available resolution.

Microcontroller 56 through microprocessor 114, which operates through a set of software algorithms that include those described further herein, independently controls the operation of positive HVPS 70 and negative HVPS 72. This set of software algorithms may be stored in a memory (not shown) accessible to microprocessor 114, and includes an ion current correction code 125. The operation of positive and negative HVPS 70 and 72, including controlling power supply power-on and power-off timing, is controlled through signals asserted by DAC output ports 126a and 126b, respectively, from digital output 118. Digital output 118, in turn, receives signals asserted by microprocessor 114 on bus 128, which causes digital output 118 to assert signals on digital output port 126a, 126b or both to control power-on or power-off power supplies 70 and 72.

For example and as shown in FIGS. 2, 3 and 5, during a first time period T1, microprocessor 114 may assert a signal (not shown) on bus 128 that will cause digital output 118 to assert a signal on digital output port 126a that will cause positive HVPS 70 to power-on, which will generate a positive voltage pulse, such as positive voltage pulse 94, that conducts to emitter module 76, causing the production of positive ions and a positive return current, such as positive return current 98 in FIG. 3. In another example and as shown in FIGS. 2, 4 and 5, during a second time period T2, microprocessor 114 may assert a signal (not shown) on bus 128 that will be processed by digital output to assert a signal on digital output port 126b that will cause negative HVPS 72 to power-on, generating a negative voltage pulse, such as negative voltage pulse 100, that conducts to emitter module 76, causing the production of negative ions and a negative return current, such as negative return current 104 in FIG. 4.

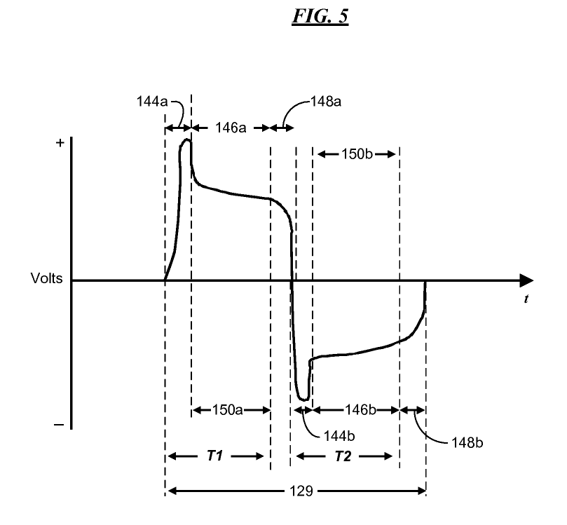

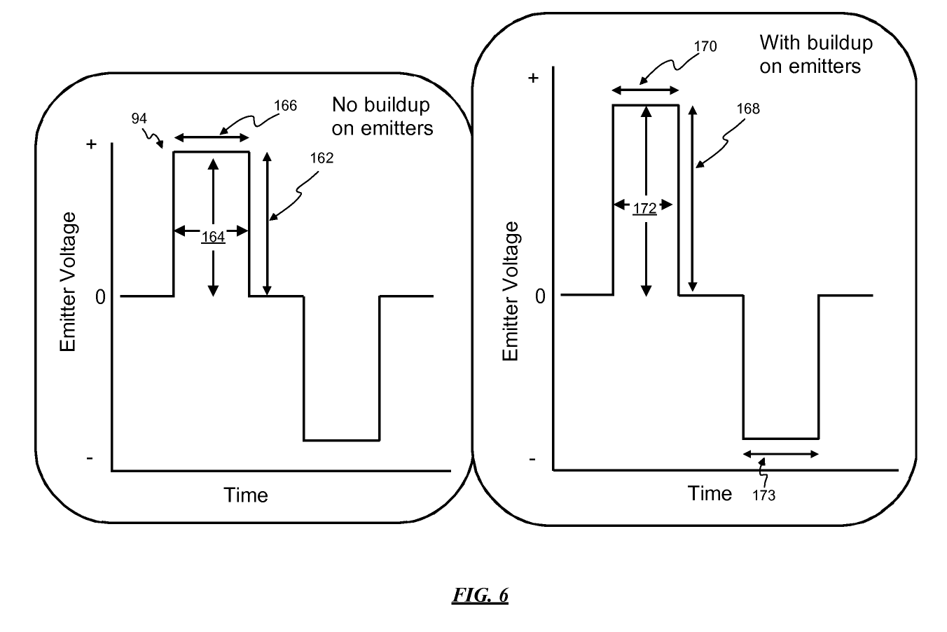

In the embodiment shown in FIGS. 2 through 5, microcontroller 56 alternates powering-on positive HVPS 70 and negative HVPS 72, causing the creation of a positive ions during at least a portion of first time period T1 and the creation of negative ions during at least a portion of second time period T2. First and second periods T1 and T2 may be selected to avoid the condition in which the positive and negative emitter voltages generated by the positive and negative HVPS 70 and 72 are received at the same time by emitter module 76. This condition may be avoided by using first and second time periods that do not overlap. The time period during which a positive emitter voltage and a negative emitter voltage are generated sequentially may be referred to as an emitter cycle 129. In FIG. 5, first and second time periods T1 and T2 occur sequentially although the order of their occurrence in the sequence shown is not intended to be limiting in anyway.

Besides controlling the operation of positive and negative HVPS 70 and 72, microcontroller 56 also controls the voltage magnitudes of the positive and negative voltage pulses 94 and 100 respectively generated by these power supplies. To facilitate the following discussion, the voltage amplitude of positive voltage pulse 94 generated during at least a portion of first time period T1 is hereinafter referred to as the positive output level. Similarly, the voltage amplitude of negative voltage pulse 100 generated during at least a portion of second time period T2 is hereinafter referred to as the negative output level.

Microcontroller 56 selects these positive and negative output levels by determining the voltage that will be asserted on the respective level control input lines, such as level control input lines 130a and 130b, of positive and negative HVPS 70 and 72. In the embodiments disclosed in FIGS. 2 through 4, voltage-controlled voltage sources 66 and 68 respectively provide voltages to level control input lines 130a and 130b, and these voltage have magnitudes that are respectively proportional to the analog voltage asserted on DAC port 122a or DAC port 122b. Voltage-controlled voltage sources 66 and 68 function as voltage amplifiers by generating voltages having magnitudes from 0 to 24 volts. These voltage magnitudes are proportional to the voltage magnitudes that may be asserted by DAC ports 122a and 122b, which in the embodiment shown are each limited to voltage magnitudes of 0 through 2.40 volts.

In turn, microprocessor 114 determines the voltage magnitudes that may be asserted by DAC ports 122a and 122b by providing a digital value to DAC 116. Microprocessor 114 selects DAC ports 122a and 122b through address or select lines 132.

Microcontroller 56 uses this digital value presented to DAC 116 to control the positive ion current and negative ion current. Microcontroller 56 selects the actual digital value by, among other things, sampling the feedback voltage received by ADC 112. To control the positive ion current, microcontroller 56 samples the ADC port, such as ADC port 110a, that is disposed to receive a voltage that represents the positive feedback voltage, such as positive feedback voltage 108a in FIG. 3. Current measuring circuit 54 generates positive feedback voltage 108a during the period in which positive ions are generated by corona discharge. To control the negative ion current, microcontroller 56 samples the ADC port, such as ADC port 110b, that is disposed to receive a voltage that represents the negative feedback voltage 108b during the period in which negative ions are generated by corona discharge. Consequently, in one embodiment of the present invention, feedback voltages are only sampled when the high voltage power supply that caused that feedback voltage to be generated is powered-on.

In a further embodiment of the present invention, microcontroller 56 may include and use program code, which may be herein after also be referred as steady-state sampling code 159 that causes the positive and negative feedback voltages generated by current measuring circuit 54 to be sampled only during the steady-state portion of the feedback voltage waveform, which avoids sampling non-useful rise and fall voltages. For example, as illustrated in FIG. 5 and during at least a portion of first time period T1, positive feedback voltage 108a may have a waveform that includes a first high-slope voltage portion that occurs during a rise-time period 144a, a low-slope or steady-state voltage portion that occurs during a steady-state period 146a and a second high-slope voltage portion that occurs during a fall-time period 148a. Similarly, during at least a portion of second time period T2, negative feedback voltage 108b may have a waveform that includes a first high-slope voltage portion that occurs during a rise-time period 144b, a low-slope or steady-state voltage portion that occurs during a steady-state period 146b and a second high-slope voltage portion that occurs during a fall-time period 148b. In accordance with one embodiment of the present invention, the emitter cycle is set at approximately 35 Hz, while rise-time period 144 and fall-time period 148 are approximately 10 ms and 8 ms, respectively.

The terms first and second high-slope voltage profiles are intended to include a portion of a feedback voltage, whether positive or negative, in which the magnitude of the feedback voltage for a given time period would not accurately reflect the amount of ion production during emitter cycle 129. The first and second high-slope voltage profiles that respectively occur during the rise-time and fall-time periods are not considered to be an optimum measure of ion output because some of the ion current produced is lost into the system's stray capacitance, causing the return current to not accurately reflect ion current flow. Steady-state period 146 reflects a period during which the return current is a good or accurate measure of air ion production. Consequently, in this alternative embodiment, the sampling period 150a or 150b taken during the first or second time periods T1 or T2 is limited to occur during steady-state period 146a or 146b, respectively.

Based on the return currents measured as described with reference with FIGS. 2 through 5, above, microcontroller 56 adjusts the magnitudes of positive and negative voltage pulses 108a and 108b, as described previously above. By sampling the feedback voltage generated by current measuring circuit 54, microcontroller 56 will be able to determine whether the ion current of a particular polarity has drifted from a prior selected setting. If so, microcontroller will calculate a control loop correction value and send a digital value through DAC 116 that will adjust the voltage magnitude of the particular voltage pulse so that ion balance for the particular positive or negative ion current may be re-established. The calculation of this control loop correction value is further described below. Thus, with the embodiments disclosed herein, the time interval between static neutralizer maintenance is increased. From the end user's viewpoint, this means that up-time is improved and cost of ownership is decreased.

Re-establishing positive and negative ion balance may be necessary where at least one emitter point has degraded or become contaminated. Contamination on an emitter reduces positive ion production more than it reduces negative ion production, which reduces or impacts charge neutralization efficiency of a static neutralizer, such as static neutralizer 52 in FIG. 2. Consequently, keeping positive and negative ion currents at preset levels, or balanced, permits a static neutralizer configured with control system 50 to maintain its charge neutralization efficiency since emitter points typically become contaminated or degrade during use overtime.

Re-establishing ion balance for such a case may require increasing the magnitude of the positive emitter voltage currently used. Increasing the magnitude of a positive emitter voltage may be required, for instance, where at least one emitter in emitter module 76 is degraded or contaminated. However, increasing the voltage received by an emitter may cause a charge plate monitor, such as CPM 80 in FIG. 2, placed near target 86 to incorrectly measure the ion current and ion current discharge time near target 86. A charge plate monitor, such as CPM 80, is commonly used in the industry to measure ion current and ion current discharge time, such as positive charge discharge time and negative charge discharge time.

In accordance with yet another embodiment of the present invention, microcontroller 56 may further include program code, which may also be referred to as E-Field compensation code herein, 160 that enables microcontroller 56 to eliminate or compensate for the effect caused on a charge plate monitor by an increase in positive voltage pulse amplitude. E-Field compensation code 160 eliminates or compensates for this effect by changing pulse time duration.

For example and with reference with FIGS. 2 and 6, microcontroller 56 may cause positive HVPS 70 to generate a positive voltage pulse, such as positive voltage pulse 94 in FIG. 6, that has amplitude 162 and a positive-pulse waveform area 164 during a positive on-time period 166. Positive on-time period 166 is defined as a time duration, also named “pulse time duration”, during which positive HVPS is powered-on and generating a positive voltage pulse, while positive-pulse waveform area 164 is equal to the product of amplitude 162 and positive on-time period 166. As previously described above, positive HVPS 70 may be implemented using a DC pulsed bipolar power supply, such as power supply 73 in FIG. 2.

If, at a time after the positive voltage pulse is created, microcontroller 56 needs to correct an ion current imbalance during the operation of static neutralizer 52 by increasing amplitude 162 to a higher value, such as amplitude 168, microcontroller 56, operating under E-field compensation code 160, may select a new positive on-time period 170 for amplitude 168 that will result in a positive-pulse waveform area 172 that is equal to the positive-pulse waveform area of the prior used positive voltage pulse, such as positive-pulse waveform area 164 and 94, respectively. In the example shown in FIG. 6, microcontroller 56 shortens the time duration of positive on-time period 170 to keep positive-pulse waveform area 172 equal to positive-pulse waveform area 164. In addition, the negative on-time period 173 may be increased by the same time duration that was used to shorten the time duration of the positive on-time period 170 if the emitter cycle is kept at a fixed frequency.

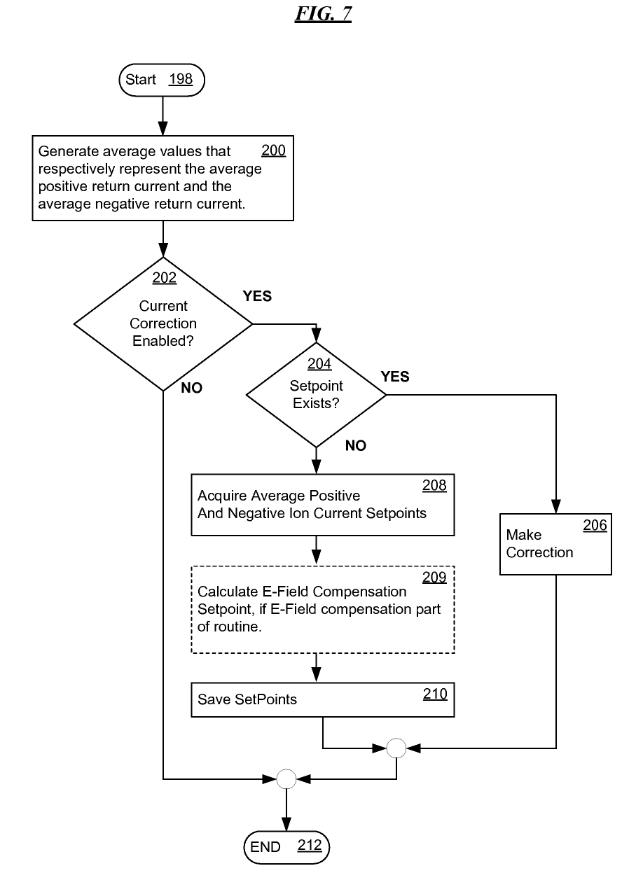

FIG. 7 is a process flow illustrating a method of maintaining ion current balance at a target location during static neutralization by independently controlling positive ion current and negative ion current in accordance with another embodiment of the present invention. This method may be performed by using a control system integrated with a static neutralizer and operating under program control. For example, the method may be performed using static neutralizer 52 that is integrated with control system 50. Control system 50 controls the operation of static neutralizer 52 through program code that includes the functionality provided by ion current correction code 125, as disclosed previously above with reference to FIGS. 2 through 4.

After entering start node 198, two average values are generated 200 that respectively represent the average positive return current value and the average negative return current value that are measured by a current measuring circuit during a selected time period. The current measuring circuit is disposed to measure return current that flows between the positive and negative HVPSs used by static neutralizer 52. For example, as shown in FIG. 2, current measuring circuit may be implemented using current measuring circuit 54, while positive and negative HVPSs may be respectively implemented using positive and negative HVPS 70 and 72. Since current measuring circuit 54 outputs a feedback voltage having a magnitude and direction that represents the magnitude and direction of current flow measured by current measuring circuit 54, the two average values are generated from samples taken through an analog-to-digital converter employed by control system 50, such as ADC 112. The selected time period, named “event period,” may be two minutes in duration although this duration is not intended to be limiting in any way. Any duration may be used for the event period as long as the duration permits control system 50 to obtain a sufficient number of values to generate an average for these values for both polarities of ion current measured by the current measuring circuit. These values are stored in memory after the values are generated.

It is then determined 202 whether ion current correction is enabled, and if so, it is further determined 204 whether a setpoint currently exists. Determining whether ion current correction is enabled may be accomplished by using control system 50, operating under program control, to determine whether a setpoint was previously saved in a memory location (not shown). If so, control system 50 retrieves the setpoint and performs 206 current correction routine that will maintain the positive and negative ion currents generated by static neutralizer 52. Otherwise, control system 50 will acquire 208 a new setpoint, save 210 the new setpoint in memory for subsequent reference and exit through end node 212.

The term “setpoint” is used to collectively refer to a set of values that are used by control system 50 to determine whether the positive and negative ion currents current produced are at a previously established level. Control system 50 also uses these values to maintain ion current if these ion currents are not in balance. These values may include a value representing an average positive return current, named “positive setpoint”, and a value representing an average negative return current value, named “negative setpoint”. The average positive and negative return current values may be generated as described in node 200, above.

In addition, if the method disclosed in FIG. 7 includes an E-Field compensation routine, an E-Field compensation value may be calculated 209 using Equation [1] below and used as an E-Field compensation value setpoint.
E-FieldSetpoint=(PosHVLevel*PosOnTime)/(NegHVLevel*(TotalOnTime−PosOnTime)) [1]

where E-FieldSetpoint is the new E-Field compensation value; PosHVLevel is the amplitude of the positive voltage pulse generated by a positive HVPS, such as positive HVPS 70; PosOnTime is the period of time positive HVPS 70 is on; NegHVLevel is the amplitude of the negative voltage pulse generated by a negative HVPS, such as negative HVPS 72; and TotalOnTime is the total time that both positive and negative HVPS 70 and 72 are on during an emitter cycle. The PosOnTime and the TotalOnTime values may be used in units of counts, with each count equal to a selected clock cycle.

Determining whether ion current correction is enabled may be performed through the use of a correction flag, which may be set through a user operated switch, the expiration of a pre-selected time period or other selected event,

If at 202, it is determined that ion current correction is not enabled 202, the method ends 212 without ion current correction.

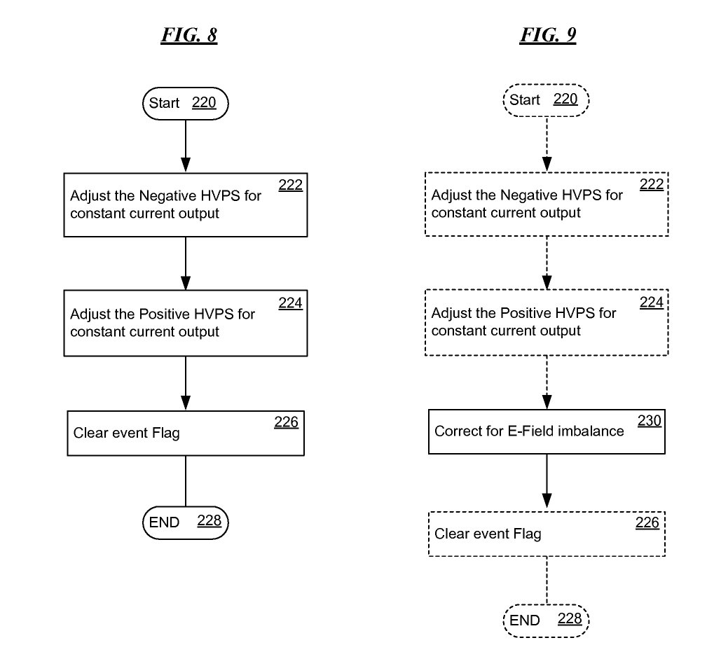

FIG. 8 illustrates a method of performing ion current correction, such as the current correction routine 206 referred to in FIG. 7, in a control system that maintains ion current balance for a static neutralizer and may include an optional routine for performing E-Field balance compensation in accordance with another embodiment of the present invention.

After entering start node 220, negative HVPS 72 is adjusted 222 so that the negative ion current generated by the negative emitter voltage produced during static neutralization remains constant. This may include adjusting the amplitude of the negative emitter voltage so that the negative return current measured by the current measuring circuit, such as current measuring circuit 54 in FIG. 4, matches an average negative return current that represents a set of negative return currents previously generated. In one embodiment, this average negative return current is in the form of an average negative feedback voltage value that was used as the negative setpoint calculated in node 208 in FIG. 7.

Positive HVPS 70 may also be adjusted 224 so that the positive ion current generated by the positive emitter voltage produced during static neutralization remains constant. This may include adjusting the amplitude of the positive emitter voltage so that the positive ion current generated by the positive emitter voltage matches an average positive ion return current that represents the average of a set of positive return currents previously generated. In one embodiment, this average positive return current is in the form of an average positive feedback voltage that was used the positive setpoint calculated in node 208 in FIG. 7.

The method in FIG. 8 may then clear 226 the current correction flag used in node 202 in FIG. 7 and exit through node 228.

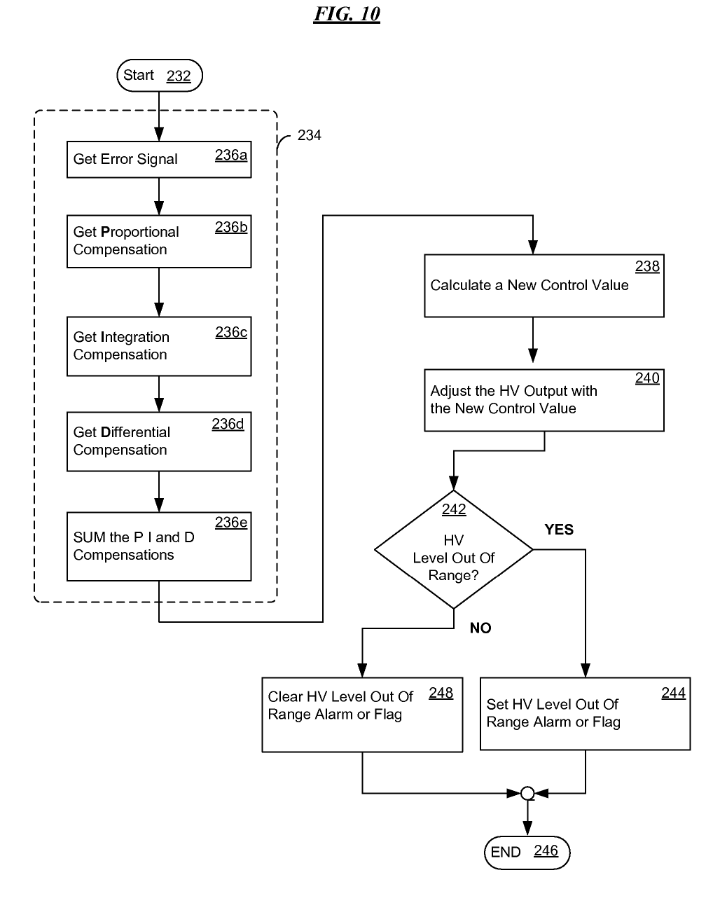

In accordance with a further embodiment of the present invention and as shown in FIG. 9, the method disclosed in FIG. 8 may be modified to further include a routine for performing E-Field balance compensation. If so, the method performs 230 an E-Field balance compensation routine before exiting through node 228.

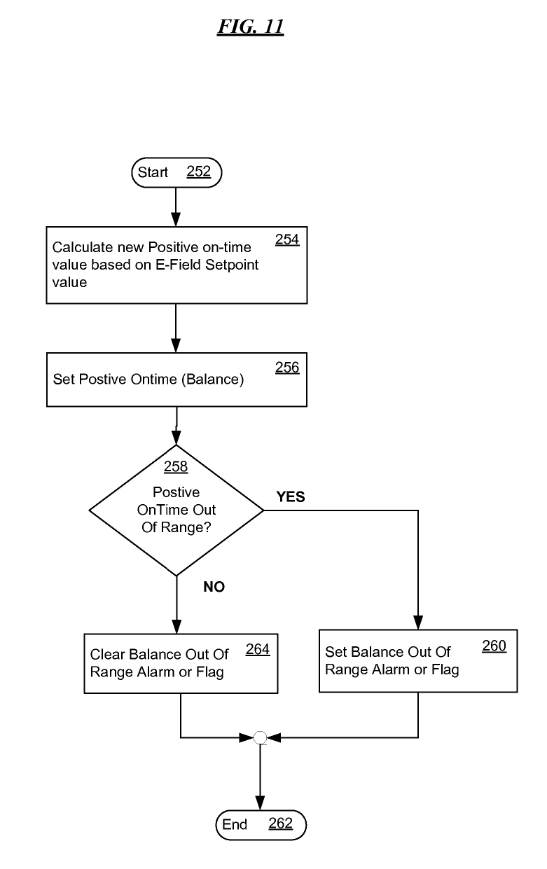

The adjustment 222 and 224 of the positive and negative voltage pulse amplitudes used for static neutralization for the method disclosed in FIG. 8 may be performed as shown in FIG. 10. The routine described in FIG. 10 is applicable to both positive and negative HVPS 70 and 72.

After entering start node 232, a compensation value is generated 234. The calculation of this compensation value may include using a PID (proportional, integration and differential) control algorithm, which is a known in the art of control loop systems. A PID control algorithm includes calculating 236a an error signal, calculating 236b a proportional compensation value, calculating 236c an integration compensation value, calculating 236d a differential compensation value and then summing 236e the proportional, integration and differential compensation values.

Calculating 236a the error signal may include using Equation [2] below:
Err=Setpoint−Calculated Average
where Err is the error signal, Setpoint is the average return current generated by the HVPS saved in 210 and the calculated average is the average return current calculated for the HVPS in 200.

Calculating 236b the proportional compensation value may include using Equation [3] below:
Pcmp=Pgain*Err
where Pcmp is the proportional compensation value, Err is the error signal calculated in Equation [2] and Pgain is a loop gain constant used for the control system, such as control system 50 in FIG. 2.

Calculating 236c the integration compensation value may include using Equation [4] below:
Icmp=Ki*ΣErr
where Pcmp is the proportional compensation value, Ki is the integration loop constant used by the control system and Err is the error signal calculated in Equation [2].

Calculating 236d the differential compensation value may include using Equation [5] below:
Dcmp=Kd*(Err−Last Err)

where Icmp is the integration compensation value, Kd is the differential loop constant used by the control system, Err is the error signal and Last Err is the error calculated using Equation [2] from a previous iteration of the method disclosed in FIG. 10.

Summing 236e the proportional, integration and differential compensation values may include using Equation [6] below:
Compensation Value=Pcmp+Icmp+Dcmp

where Pcmp is the proportional compensation value calculated in 236b, Tcmp is the integration compensation value calculated in 236c and Dcmp is the differential compensation value calculated in 236d. In an alternative embodiment of the present invention, the compensation value may be calculated using only one or two of the proportional, integration and differential compensation values.

After a compensation value is generated 234, a new control value is generated 238 by adding the compensation value with the control value currently used by control system 50. This control value may be in the form of a 12 bit digital value. The control value is used to adjust 240 the voltage pulse amplitude of the HVPS selected for adjustment. In one embodiment and with reference to FIG. 2, microprocessor 114 may present the digital value to DAC 116 so that DAC 116 asserts a voltage output through a DAC port that is coupled to a level control line, whether directly or through a voltage controlled voltage source, of the HVPS whose voltage pulse amplitude is being adjusted, causing the HVPS to adjust the voltage pulse amplitude generated by the HVPS.

This digital value is checked 242 to determine whether it is outside of the possible range of control of the control system, and if so, a high voltage out of range flag or bit is set and the routine ends 246. If the digital value is not outside of the possible range of control, the high voltage out or range flag or bit is cleared.

FIG. 11 is a method of performing E-Field compensation that may be used with the method in FIG. 8 above in accordance with yet another embodiment of the present invention.

After entering start node 252, a new positive on-time period is calculated 254 by using Equation [7] below:

$$NewPosOnTime = ( \frac{E - FieldSetPoint * ( NegHVLevel ) * ( TotalOnTine )}{PosHVLevel + ( E - FieldSetPoint * ( NegHVLevel ) )} )$$

where NewPosOnTime is the new positive on-time period; PosHVLevel is the amplitude of the positive voltage pulse generated by the positive HVPS; E-FieldSetPoint is equal to the E-Field compensation setpoint calculated in Equation [1] above; NegHVLevel is the amplitude of the negative voltage pulse by the negative HVPS; TotalOnTime is the total time (in counts) that both HVPS are on during an emitter cycle

The new positive on-time value is applied 256 to the digital output 118, and it is determined 258 whether the new value is within the range of the control.

If it is found out of the range of control, out-of-range alarm, flag or equivalent is set 260 and the function ends 262. Otherwise, the out-of-range alarm or flag is cleared 264 and the function proceeds to end node 262.

While the present invention has been described in particular embodiments, it should be appreciated that the present invention should not be construed as limited by such embodiments. Rather, the present invention should be construed according to the claims below.

We claim:

1. An apparatus for maintaining the ion balance of a set of positive and negative ions that are generated by a static neutralizer, the apparatus comprising:
a first high voltage source for providing a positive high voltage to an emitter module;
a second high voltage source for providing a negative high voltage to said emitter module;
a current measuring circuit electrically coupled to said positive and said negative high voltage sources and to ground, said current measuring circuit having an output;
a control means electrically coupled to said current measuring circuit and said positive and said negative high voltage sources;
wherein during a first on-time period, said control means causes said positive high voltage source to provide said positive high voltage, and wherein during a second on-time period, said control means causes said negative high voltage source to provide said negative high voltage;
wherein said control means obtains a first signal indicative of a positive return-current flowing between at least one emitter from said emitter module and said ground by sampling said output during at least a first portion of said first on-time period;
wherein said control means obtains a second signal indicative of a negative return-current flowing between said at least one emitter and said ground by sampling said output during at least a second portion of said second on-time period; and
wherein said control means uses said first signal and said second signal to cause an adjustment of said positive high voltage and said negative high voltage, respectively.

2. The apparatus of claim 1:
further including a summing block electrically coupled to said first and said second high voltage sources; and
wherein said at least one emitter is coupled to said summing block.

3. The apparatus of claim 1, wherein said at least one emitter includes a first emitter and a second emitter; said emitter disposed to receive said positive high voltage, and said second emitter disposed to receive said negative high voltage.

4. An apparatus for controlling ion current balance by independently controlling positive ion current and negative ion current generated by a static neutralizer, the apparatus comprising:
a first high voltage source for providing a positive voltage pulse to a first emitter, said positive voltage pulse having a first amplitude;
a second high voltage source for providing a negative voltage pulse to a second emitter, said negative voltage pulse having a second amplitude;
a current measuring circuit for providing a voltage proportional to current received by said current measuring circuit, said current measuring circuit coupled to said positive and said negative high voltage sources;
a control circuit electrically coupled to said current measuring circuit and said positive and said negative high voltage sources;
wherein said control circuit activates said positive high voltage source and samples a first set of voltage values representing said voltage provided by said current measuring circuit during a first time period;
wherein said control circuit activates said negative high voltage source and samples a second set of voltage values representing voltages provided by said return current measuring circuit during a second time period; and
wherein said control circuit uses said first and said second set of voltage values to adjust said first and second amplitudes during said first and second time periods to control the positive ion current and the negative ion current, respectively, of the static neutralizer.

5. The apparatus of claim 4, wherein said current measuring circuit includes a resistor electrically coupled to said first and second high voltage sources, to ground and to said control circuit.

6. The apparatus of claim 4, wherein said control circuit includes a sampling circuit for sampling said first and second voltage values during said first and said second time periods.

7. The apparatus of claim 6, wherein:
said sampling circuit includes a first rectifier, a second rectifier and an analog to digital converter and further including a computing device electrically coupled to receive a digital output from said analog to digital converter;
wherein said first rectifier is electrically disposed to permit said analog to digital converter to receive only said first voltage value; and
wherein said second rectifier is electrically disposed to said analog to digital converter to receive only said second voltage.

8. The apparatus of claim 4:
wherein said current measuring circuit includes a resistor that has a first end electrically coupled to said first and said second high voltage sources and a second end electrically coupled to ground;
further including a sampling circuit having a first precision rectifier, a second precision rectifier and an analog to digital converter, and a computing device electrically coupled to receive a digital output from said analog to digital converter;
wherein said first precision rectifier is electrically coupled to said first end and to said analog to digital converter, said first precision rectifier permitting only positive voltages to be received by said analog to digital converter;
wherein said second precision rectifier is electrically coupled to said first end and to said analog to digital converter, said second precision rectifier permitting only negative voltages to be received by said analog to digital converter.

9. The apparatus of claim 8, wherein said first rectifier is implemented using an active circuit;

10. The apparatus of claim 8, wherein said first rectifier is implemented using a precision rectifier.

11. The apparatus of claim 4, further including a summing block having an output coupled to said first and said second emitters, said summing block disposed to received said first and said second having a first input, a second input respectively coupled to said positive and said negative voltage pulse.

12. The apparatus of claim 4, further including a memory for storing a computer program;
wherein said computer program causes said control circuit to calculate an first average voltage value from said first set of voltage values and a second voltage value from said second set of voltage values; and
wherein in response to a selected signal, said computer program causes said control circuit to acquire a positive and a negative setpoints if said positive and negative setpoints are not available, or causes said control circuit to perform an ion current correction routine if said positive and negative set points are available.

13. The apparatus of claim 12, wherein:
said control circuit calculates said first average value by sampling said first set of voltage values only during said first time period; and
said control circuit calculates said second average value by sampling said second set of voltage values only during said second time period.

14. The apparatus of claim 12, wherein said control circuit performs said ion current correction routine by calculating a control loop correction value and by using said control loop correction value to adjust said first amplitude.

15. The apparatus of claim 14, wherein said control circuit calculates said control loop compensation by calculating a control loop error, said calculating a control loop error including calculating a difference between said positive setpoint and said first average voltage value.

16. The apparatus of claim 15, wherein said computer program cause said control circuit to assert a first control value which reflects said control loop correction value, said first control value used to adjust said first amplitude.

17. The apparatus of claim 15, wherein said computer program cause said control circuit to assert a second control value which reflects said control loop correction value and is used to adjust said second amplitude.

18. The apparatus of claim 14, wherein said control loop correction value is a sum including any one of a proportional compensation value; an integration compensation value and a differential compensation value.

19. The apparatus of claim 12, wherein a status flag is set if said ion current correction routine results in said first amplitude exceeding a selected threshold.

20. The apparatus of claim 4:
further including a memory for storing an E-Field compensation program;
wherein said positive voltage pulse has a positive-pulse waveform and a first positive on-time period of a first duration; and
wherein said E-Field compensation program keeps a subsequent positive-pulse waveform of a subsequent positive voltage pulse equal to said positive pulse waveform.

21. The apparatus of claim 20, wherein:
said subsequent positive pulse voltage has a second positive on-time period of a selected duration; and
said E-Field compensation program keeps said subsequent positive-pulse waveform equal to said positive pulse waveform by keeping said second duration less than said first duration by a selected amount.

22. The apparatus of claim 21, wherein said E-Field compensation program keeps a third duration more than said second duration, said third duration from a negative on-time period for a subsequent negative voltage pulse, said third duration exceeding said second duration by said selected amount.

23. A machine-readable storage memory containing a set of computer program instructions for controlling positive ion current and negative ion current of a static neutralizer, said static neutralizer including: a first high voltage source for providing a positive high voltage to an emitter module; a second high voltage source for providing a negative voltage pulse to said emitter module; a current measuring circuit electrically coupled to said positive and said negative high voltage sources and to ground, said current measuring circuit having an output; a control means electrically coupled to said current measuring circuit and said positive and said negative high voltage sources; said set of computer program instructions comprising:
a first set of program instructions for causing the control means, during a first on-time period, to cause the positive high voltage source to provide the positive voltage pulse, and for causing the control means, during a second on-time period, to cause the negative high voltage source to provide the negative voltage pulse;
a second set of program instructions for causing the control means to obtain a first signal indicative of a positive return-current flowing between the emitter module and ground by sampling the output during at least a first portion of the first on-time period;
a third set of program instructions for causing the control means to obtains a second signal indicative of a negative return-current flowing between the emitter module and ground by sampling the output during at least a second portion of the second on-time period; and
a fourth set of program instructions for causing the control means to use said first signal and said second signal to cause an adjustment of the positive voltage pulse and the negative voltage pulse, respectively.

24. The machine-readable storage memory of claim 23, further comprising a fifth set of program instructions for performing an E-Field compensation routine.

25. A static neutralizer for removing static charge from a target using air ions or gas ions, which includes:
a plurality of emitters;
a positive high voltage power supply;
a negative high voltage power supply;
one return-from-ground feedback current;
a microprocessor that receives said one return-from-ground feedback current signal.

26. The static neutralizer of claim 1, where said positive high voltage power supply and said negative high voltage power supply are connected to the same emitters through a summing block.

27. The static neutralizer of claim 1, where said positive high voltage power supply and said negative high voltage power supply are connected to positive emitters and negative emitters respectively.

28. The static neutralizer of claim 1, said microprocessor plus two precision rectifiers separate said one return-from-ground feedback current into positive and negative current components.

29. The static neutralizer of claim 1, where said return-from-ground feedback current flows through an output resistor to create a feedback voltage drop.

30. The static neutralizer of claim 29, where said feedback voltage drop is proportional to said return-from-ground feedback current, and said feedback voltage drop is received by said microprocessor.

31. The static neutralizer of claim 29, where a low pass filter is disposed between the ungrounded side of said output resistor and said microprocessor.

32. The static neutralizer of claim 29, where an analog-to-digital converter is disposed between the ungrounded side of said output resistor and said microprocessor.

33. The static neutralizer of claim 29, where a positive precision rectifier and a negative precision rectifier are disposed between the ungrounded side of said output resistor and said microprocessor.

34. The static neutralizer of claim 25, where said microprocessor sends digital output signals that independently turn said positive high voltage power supply and said negative high voltage power supply on and off.

35. The static neutralizer of claim 25, where said microprocessor sends analog output signals that independently control the voltage amplitude of said positive high voltage power supply and said negative high voltage power supply.

36. The static neutralizer of claim 25, where said microprocessor is programmed to ignore the return-from-ground feedback current at predetermined times.

37. The static neutralizer of claim 36, where said predetermined times correspond to the rise time or the fall time of said return-from-ground feedback current.

38. The static neutralizer of claim 25, where the grounded sides of said positive high voltage power supply and said negative high voltage power supply are electrically connected.

39. The static neutralizer of claim 38, where said grounded sides of said positive high voltage power supply and said negative high voltage power supply are further connected to the ungrounded side of an output resistor.

40. A feedback method for controlling a pulsed DC ionizer, which includes:
connecting a first ground rail of a first power bus from a positive power supply used by the pulsed DC ionizer with a second ground rail of a first power bus from a negative power supply used by the pulsed DC ionizer;
connecting an output resistor to said first and second ground rails and to earth ground;
using a voltage generated when a current flows across said output resistor as a feedback signal to a microprocessor; and
generating control signals with said microprocessor that control said positive high voltage power supply and said negative high voltage power supply.

41. The method of claim 40 where said current is bidirectional.

42. The method of claim 40, where said current direction is determined by which power supply is applying power to said ionizer's emitters.

43. The method of claim 40, where said control signals from said microprocessor include both analog and digital signals.

44. The method of claim 40, where an analog-to-digital converter is positioned between microprocessor and said output resistor.

45. The method of claim 40 where the output of said positive high voltage power supply and said negative high voltage power supply are connected to emitters through a summing block.

46. The method of claim 40 further comprising a step for delaying said microprocessor's acquisition of feedback signal at predetermined time intervals.

47. The method of claim 46 where said delaying is used to remove the rise and fall portions of said feedback signal.

48. A method of adjusting the voltage of ionizer emitters in a static neutralizer to maintain balance without causing drift on a charge plate monitor near a target, said static neutralizer generating an ion current during static neutralization of said target, the method comprising:
sensing changed emitter output by measuring a return current;
increasing emitter voltage to compensate for a decrease the ion current; and
reducing a pulse time of said emitter voltage.

49. The method of claim 48, where a product of said pulse time and said emitter voltage remains constant during said reducing.

50. The method of claim 48, where said reducing is controlled by a microprocessor and an E-Field compensation routine.

51. An apparatus for maintaining the ion current balance of a static neutralizer, the apparatus comprising:
a DC pulsed bi-polar power supply for providing a positive voltage pulse and a negative voltage pulse to an emitter module;
a current measuring circuit electrically coupled to said DC pulsed bi-polar power supply, and to ground, said current measuring circuit having an output;
a control means electrically coupled to said current measuring circuit and said DC pulsed bi-polar power supply;
wherein during a first on-time period, said control means causes said DC pulsed bi-polar power supply to provide said positive high voltage, and wherein during a second on-time period, said control means causes said DC pulsed bi-polar power supply to provide said negative high voltage;
wherein said control means obtains a first signal indicative of a positive return-current flowing between at least one emitter from said emitter module and said ground by sampling said output during at least a first portion of said first on-time period;
wherein said control means obtains a second signal indicative of a negative return-current flowing between said at least one emitter and said ground by sampling said output during at least a second portion of said second on-time period; and
wherein said control means maintains the ion current balance of the static neutralizer by using said first signal and said second signal to cause an adjustment of said positive high voltage and said negative high voltage, respectively.

52. The apparatus of claim 51, wherein said DC pulsed bi-polar power supply includes a first high voltage source for generating said positive high voltage; and a second high voltage source for generating said negative high voltage.

53. The apparatus of claim 51, wherein said control means is a microcontroller.
